(19) United States
(12) Patent Application Publication
(10) Pub. No.: US 2004/0266136 A1
(43) Pub. Date: Dec. 30, 2004

(54) Method for fabricating semiconductor device having trench type device isolation layer

(76) Inventors: Tae-Woo Jung, Ichon-shi (KR); Jun-Hyeub Sun, Ichon-shi (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/750,021

(22) Filed: Dec. 30, 2003

(30) Foreign Application Priority Data
Jun. 30, 2003 (KR) 2003-43071

(51) Int. Cl. H01L 21/76

(52) U.S. Cl. 438/437

(57) ABSTRACT

A method for fabricating a semiconductor device with a trench type device isolation layer capable of controlling a rounding angle of top corners of a trench and removing damaged layers formed after etching the trench. Particularly, the top corners of the trench is manipulated to have an angle of about 30° to about 60° by using a gas containing at least hydrogen bromide and chlorine gas. Then, an isotropic etching technique is performed as a light etch treatment to make the top corners have an angle of about 50° to about 80°. Finally, a dry oxidation technique is performed to form a screen oxide layer and a gate oxide layer so that moat generations are minimized prior to forming a gate electrode.

### FIELD OF THE INVENTION

The present invention relates to a method for fabricating a semiconductor device; and, more particularly, to a semiconductor device having a device isolation layer with a trench structure.

### DESCRIPTION OF RELATED ARTS

Generally, a field region defining an active region is formed by depositing a field insulation layer on a predetermined region of a semiconductor device. Particularly, the field insulation layer is formed by employing a device isolation (ISO) process such as a local oxidation of silicon (LOCOS) process and a profiled groove isolation (PGI) process.

For the LOCOS process, a nitride layer, which is an oxidation mask defining an active region, is formed on a substrate. Then, the nitride layer is patterned by using photolithography to make a predetermined portion of the substrate exposed. Afterwards, the exposed portion of the substrate is oxidated to form a field oxide layer used as a device isolation region.

The LOCOS process is simple and is capable of isolating a wide area and a narrow area simultaneously. Despite these advantages, a width of the device isolation region becomes wider due to a bird's beak effect generated by a lateral oxidation, and thereby decreasing an effective area of a source/drain region. Also, during the formation of the field oxide layer, stress exerted by a difference in thermal expansion coefficients is concentrated in edge regions of the field oxide layer. Therefore, the substrate, which is made of silicon, has a defect in crystal, further resulting in leakage currents.

Large-scale integration of a semiconductor device leads to the reduction of an applicable design rule, and thus, the size of the device isolation layer is decreased by the same scale of the reduced design rule. Therefore, there is a limitation in applying the conventional LOCOS and poly buffered LOCOS (PBL) to the reduced design rule.

Therefore, a shallow trench isolation (STI) process is developed to solve the problems caused by the conventional LOCOS and PBL processes. According to the STI process, a nitride layer having a good etch selectivity with respect to a substrate is formed on the substrate, and the nitride layer is patterned by photolithography. The substrate is patterned to a predetermined depth through the use of a dry etching process to form a trench. At this time, the patterned nitride layer is used as a hard mask. An insulation layer is filled into the trench and is subjected to a chemical mechanical polishing (CMP) process to form a field oxide layer buried into the trench.

FIGS. 1A and 1B are cross-sectional views illustrating a method for forming a conventional device isolation layer with a trench structure.

Referring to FIG. 1A, a pad oxide layer 12 and a pad nitride layer 13 are deposited on a substrate 11. A photosensitive pattern (not shown) defining a device isolation region is formed on the pad nitride layer 13, and the pad nitride layer 13 and the pad oxide layer 12 are sequentially etched with use of the photosensitive pattern as an etch mask until a surface of the substrate 11 is exposed.

Next, the photosensitive pattern is striped away. The pad oxide layer 12 is etched. Then, the exposed portion of the substrate 11 is etched to a predetermined depth by performing a dry etching process so that a trench 14 is formed. Subsequent to the dry etching process, a lateral oxidation process for removing damaged layers caused by the etching for forming the trench 14 is performed to form a lateral oxide layer 15 at a bottom side and lateral sides of the trench 14.

Afterwards, a liner nitride layer 16 is deposited on an entire surface of the above constructed structure, and an oxide layer 17 is deposited with use of a high density plasma technique to fill the trench 14.

Referring to FIG. 1B, a CMP process is performed to the oxide layer 17 until a surface of the pad nitride layer 13 is exposed. From this CMP process, a device isolation layer made of the oxide layer 17 is formed. Hereinafter, the oxide layer 17 is referred to as the device isolation layer. Thereafter, the pad nitride layer 13 and the pad oxide layer 12 are removed through a wet etching process.

However, the conventional trench 14 formed after the dry etching process has sharply edged top corners. In other words, the top corners of the trench 14 have a narrow rounding angle A measured from an upper most surface of the above resulting substrate structure to the etched top corner of the trench 14. Thus, an electric potential is concentrated into these sharply edged top corners, further lowering a threshold voltage of a transistor.

During the removal of the pad nitride layer 13 and the pad oxide layer 12, top corner portions of the device isolation layer 17 are also etched, and thereby forming moats, i.e., a height difference between the active region and the device isolation layer 17. Herein, the moat is denoted as M in FIG. 1B. However, the moat M causes a portion of a polysilicon layer deposited and subjected to a dry etching process for forming a gate electrode still to remain on the moat M and thus to form a bridge between neighboring gate electrodes. That is, the remnant polysilicon layer remains on the moat M since the subsequent processes are performed under the state that the trench has sharply edged top corners.

Also, after the dry etching process for forming the trench 14, a lateral oxidation process is performed to remove the damaged layers by the dry etching. However, this lateral oxidation process may not be sufficient to remove the damaged layers by the dry etching.

### SUMMARY OF THE INVENTION

It is, therefore, an object of the present invention to provide a method for fabricating a semiconductor device having a trench type device isolation layer having rounded top corners.

It is another object of the present invention to provide a semiconductor device having a trench type device isolation layer capable of removing damaged layers resulted from an etching process for forming a trench.

In accordance with an aspect of the present invention, there is provided a method for forming a device isolation layer of a semiconductor device, including the steps of: forming a pad layer pattern defining a device isolation layer on a substrate; forming a trench by etching an exposed portion of the substrate with use of the pad layer pattern as a mask; performing an etching process to make top corners of the trench rounded; forming a lateral oxide layer by oxidating sidewalls of the trench formed after the etching process; forming a liner nitride layer on the lateral oxide layer; forming an insulation layer on the liner nitride layer to fill the trench; and planarizing the insulation layer.

In accordance with another aspect of the present invention, there is also provided a method for fabricating a semiconductor device, including the steps of: forming a trench of which top corners are rounded by etching a surface of a substrate to a predetermined depth; performing an etching process to the trench so that the top corners of the trench become more rounded; forming a lateral oxide layer by oxidating sidewalls of the trench; forming a liner nitride layer on the lateral oxide layer; forming an insulation layer on the liner nitride layer to bury the trench; planarizing the insulation layer until a surface of the substrate is exposed; forming an oxide layer on the exposed surface of the substrate; and forming a conductive layer for a gate electrode on an entire surface of a structure containing the oxide layer.

### BRIEF DESCRIPTION OF THE DRAWING(S)

The above and other objects and features of the present invention will become apparent from the following description of the preferred embodiments given in conjunction with the accompanying drawings, in which:

FIGS. 1A and 1B are cross-sectional views illustrating a method for fabricating a conventional semiconductor device having a trench type device isolation layer;

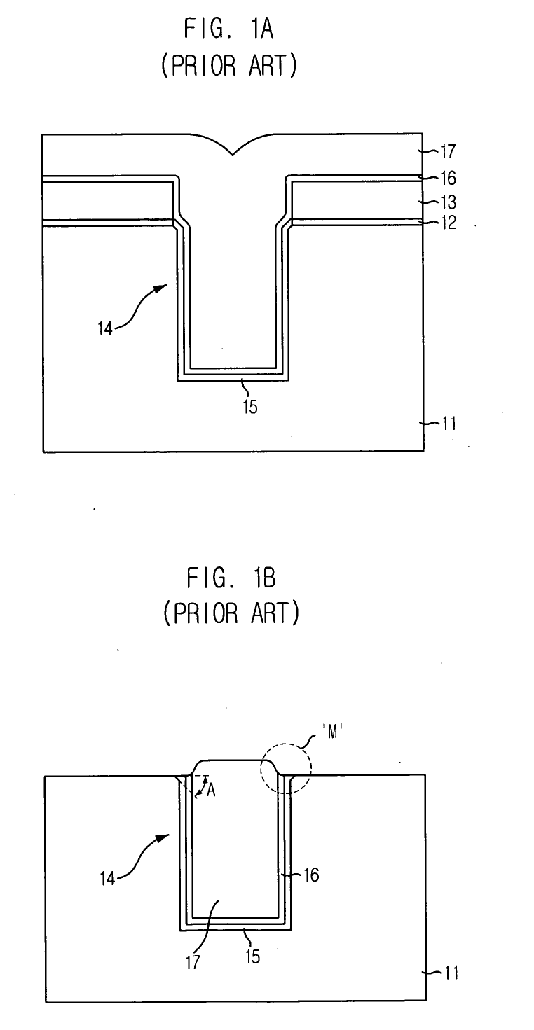

FIGS. 2A to 2H are cross-sectional views illustrating a method for fabricating a semiconductor device having a trench type device isolation layer in accordance with a preferred embodiment of the present invention;

FIG. 3A is a detailed diagram showing changes in a top rounding angle of a top corner of the trench during an etching process for forming the trench, a subsequent light etch treatment (LET) and deposition of a liner nitride layer;

FIG. 3B is a detailed diagram showing a change in the top corner angle of the trench during deposition of a screen oxide layer and a gate oxide layer;

FIG. 3C shows a change in thickness of an oxide layer formed at the top corner of the trench;

FIG. 4A is a micrograph showing a case of forming the top corner of the trench at an angle of about 30° under a predetermined etching condition;

FIG. 4B is a micrograph showing a case of forming the top corner of the trench at an angle of about 45° under a predetermined etching condition;

FIG. 4C is a micrograph showing a case of forming the top corner of the trench at an angle of about 90° under a predetermined etching condition;

FIGS. 5A to 5C are micrographs showing resultant structures constructed by performing a LET to the trench with the top corner rounded at an angle of about 45° and subsequently depositing a liner nitride layer thereon;

FIG. 5D is a micrograph showing a resultant structure after depositing the liner nitride layer without performing the LET;

FIG. 6A is a micrograph showing the result after depositing the liner nitride layer as shown in FIG. 5C and then removing a pad nitride layer;

FIG. 6B is a micrograph showing a resultant structure after forming the screen oxide layer;

FIG. 6C is a micrograph showing a resultant structure after forming the gate oxide layer;

FIG. 7 is a graph comparing a decrease in the width of the active region when performing the LET to that in the width of the active region without performing the LET; and

FIG. 8 is a graph showing changes in the width of the active region after removing the pad nitride layer.

### DETAILED DESCRIPTION OF THE INVENTION

Hereinafter, a method for fabricating a semiconductor device having a device isolation layer with a trench structure will be described in more detail with reference to the accompanying drawings.

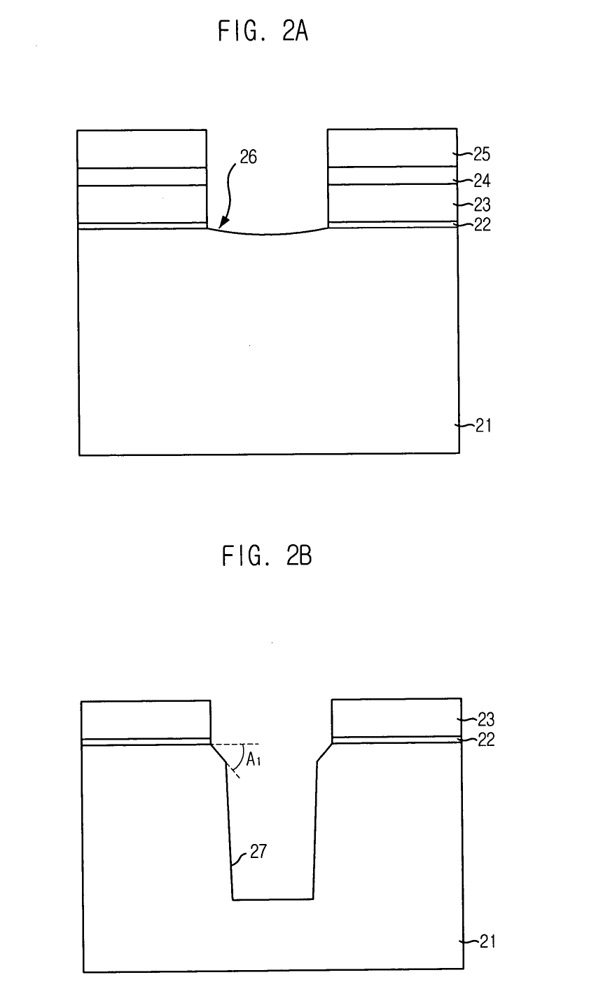

FIGS. 2A to 2H are cross-sectional views illustrating a method for fabricating a semiconductor device having a device isolation layer with a trench structure in accordance with a preferred embodiment of the present invention.

Referring to FIG. 2A, a pad oxide layer 22 and a pad nitride layer 23 are sequentially formed on a silicon substrate 21. Herein, the pad nitride layer 23 functions as an etch stop layer during a subsequent etching process and also as a polishing stop layer during a subsequent chemical mechanical polishing (CMP) process. Preferably, the pad oxide layer 22 is a silicon oxide (SiO₂) layer having a thickness of about 100 Å, and the pad nitride layer 23 is a silicon nitride (Si₃N₄) layer having a thickness ranging from about 300 Å to about 2000 Å.

Next, an anti-reflection layer 24 is formed on the pad nitride layer 23. Herein, the anti-reflection layer 24, which is a silicon nitride (SiN) layer, is adopted to perform easily a photolithography process.

A photosensitive layer is then coated on the anti-reflection layer 24 and is patterned by employing a photo-exposure and developing process so that a photosensitive pattern 25 defining a device isolation region is formed. Afterwards, the anti-reflection layer 24, the pad nitride layer 23 and the pad oxide layer 22 are sequentially etched with use of the photosensitive pattern 25 as an etch mask. The etching process takes place at a pad nitride layer etching device and proceeds in four steps of: etching the anti-reflection layer 24; etching the pad nitride layer 23; over-etching the pad nitride layer 23; and forming a top rounded surface 26.

More specific to these four steps, the anti-reflection layer 24 is etched by using the photosensitive pattern 25 as an etch mask. At this time, the etching proceeds by using a gas mixed of CH₃, CF₄, Ar and O₂, and a point of terminating the etching is set by an end of point (EOP), which is an etch stop point. For example, a single or mixed gas of CHF₃ with a flow quantity ranging from about 10 sccm to about 30 sccm, CF₄ with a flow quantity ranging from about 20 sccm to about 30 sccm or O₂ ranging from about 5 sccm to about 20 sccm is used as an etch gas for the above etching process for etching the anti-reflection layer 24. Particularly, for the mixed etch gas, the CF₄ gas has the highest absolute flow quantity.

Then, the pad nitride layer 23 exposed after etching the anti-reflection layer 24 is etched. At this time, the same etch gas is used with the same recipe. For instance, a mixed gas of CHF₃, CF₄, Ar and O₂ is used as an etch gas, and a point of terminating the etching process is set by an EOP, which is an etch stop point. Preferably, the etch gas is obtained by mixing CHF₃ with a flow quantity of about 5 sccm to about 30 sccm, CF₄ with a flow quantity of about 5 sccm to about 15 sccm or O₂ with a flow quantity of about 0 sccm to about 10 sccm. At this time, for the mixed etch gas, the CHF₃ gas has the highest absolute flow quantity. The pad oxide layer 22 is also etched when the pad nitride layer 23 is etched.

As a next step, the pad nitride layer 23 is subjected to an over-etching process. The over-etching process is to eliminate any defect like a silicon spot formed at a surface of the silicon substrate 21 after the pad nitride layer 23 and the pad oxide layer 22 are etched. A mixed gas of CF₄, Ar and O₂ is used as an etch gas for the over-etching process.

Subsequent to the over-etching process, an initial top rounded surface 26 is formed prior to forming a trench. At this time, a mixed gas of CHF₃, CF₄ and Ar is used.

Referring to FIG. 2B, after the etching process applied to the pad nitride layer 23, the photosensitive pattern 25 and the anti-reflection layer 24 are stripped away by using oxygen plasma.

A portion of the silicon substrate 21 is then etched by using the pad nitride layer 23 as an etch mask to proceed a process for forming a trench 27. This etching process for forming the trench 27 includes four steps of: controlling a rounding angle A1 of top corners of the trench 27 by etching the top corners with use of hydrogen bromide (HBr); removing a native oxide layer; etching the silicon substrate 21 to a predetermined depth; and purging a gas used during the etching process. This etching process takes place at a silicon substrate etching device. Also, the above mentioned rounding angle is measured from an upper surface of the silicon substrate 21 to the etched corner of the trench 27.

For the first step of controlling the rounding angle A1, a gas containing HBr can be used as an etch gas. Also, He gas can be added to the above etch gas. For the second step of removing the native oxide layer, a mixed gas of CF₄ and He is used as an etch gas. The third step of etching the silicon substrate 21 is a main etching step of forming the trench 27. For the third step, a gas containing a mixed gas of HBr and chlorine (Cl₂) gas is used as an etch gas. For instance, such gas as HBr, Cl₂, O₂ and He is used for the etch gas. For the fourth step, a mixed gas of CF₄, O₂, Ar and He is used to purge the chlorine gas from the chamber.

After the etching process for forming the trench 27, the top corners of the trench 27 are set to have the rounding angle A1 in a range from about 30° to about 60°. That is, the top corners are etched in an angle of about 30° to about 60° with respect to the upper surface of the silicon substrate 21 so that slant sidewalls are formed.

Referring to FIG. 2C, an isotropic etching technique is performed as a light etch treatment (LET) for etching additionally the trench 27. At this time, the top corners of the trench 27 have a rounding angle A2 of about 50° to about 80° by performing the isotropic etching technique using a mixed gas of CF₄ and O₂.

In addition, the isotropic etching process removes those layers damaged during the etching of the trench 27 and controls the rounding angle A2 of the top corners of the trench 27 to be in a range from about 50° to about 80°. For instance, since the isotropic etching technique etches more the top corners of the trench 27 rounded in about 30° to about 60° than sidewalls of the trench 27 that is nearly vertical, the rounding angle A1 of the top corners can be sharply sloped by the isotropic etching technique.

Referring to FIG. 2D, a lateral oxide layer 28 is formed at the sidewalls of the trench 27 by performing a lateral oxidation process. At this time, the lateral oxidation process for forming the lateral oxide layer 28 proceeds at a temperature ranging from about 900° C. to about 1000° C. by employing a dry oxidation technique. The lateral oxide layer 28 has a thickness ranging from about 60 Å to about 100 Å, and the top corners of the trench 27 has a rounded angle A3 ranging from about 85° to about 90° after the formation of the lateral oxide layer 28. However, the dry oxidation technique oxidates the top corners in more extents compared to a wet oxidation technique, and thus, the lateral oxide layer 28 formed at the top corners has a thickness D2 thicker than a thickness D1 of the lateral oxide layer 28 formed at sidewalls of the trench 27.

Referring to FIG. 2E, a liner nitride layer 29 is deposited along a profile containing the trench 27 and the lateral oxide layer 28. An insulation layer 30 is deposited on the liner nitride layer with use of a high density plasma technique until the insulation layer 30 is filled completely into the trench 27.

Referring to FIG. 2F, the insulation layer 30 is then planarized by employing a chemical mechanical polishing (CMP) process, and the pad nitride layer 23 is removed by using a wet solution of phosphoric acid (H₃PO₄). At this time, the lateral oxide layer 28 is not etched since the pad oxide layer 23 and the lateral oxide layer 28 have different etch selectivity to the phosphoric acid solution.

After the removal of the pad nitride layer 23, a device isolation layer formed with the insulation layer 30 is formed by removing the pad oxide layer 22 through a wet etching process. At this time, the lateral oxide layer 28 covering the top corners of the trench 27 has a thickness thicker than the thickness of the trench 27 formed at the sidewalls of the trench. Thus, generations of moat are minimized after the removal of the pad oxide layer 22.

Referring to FIG. 2G, a screen oxide layer 31 is formed by employing a dry oxidation technique, and impurities for controlling a threshold voltage are ion-implanted. At this time, the screen oxide layer 31 is formed at a temperature ranging from about 850° C. to about 1000° C. with a thickness of about 50 Å to about 150 Å.

Referring to FIG. 2H, the screen oxide layer 31 is removed, and then, a dry oxidation technique is performed again to form and grow a gate oxide layer 32. At this time, the gate oxide layer 32 is formed at a temperature ranging from about 850° C. to about 1000° C. Also, a wet oxidation technique can be also used instead of the dry oxidation technique. Since the screen oxide layer 31 and the gate oxide layer 32 are formed through the use of the dry oxidation technique, it is possible to maintain an angle of the top corners to be about 90°.

As a subsequent process to the dry oxidation technique applied to form the gate oxide layer 32, a polysilicon layer can be also deposited on the gate oxide layer 32 with a state of the minimum moat generations and is then subjected to the etching process. In that case of depositing and etching the polysilicon layer, it is possible to prevent any remnant layer from remaining on the moat.

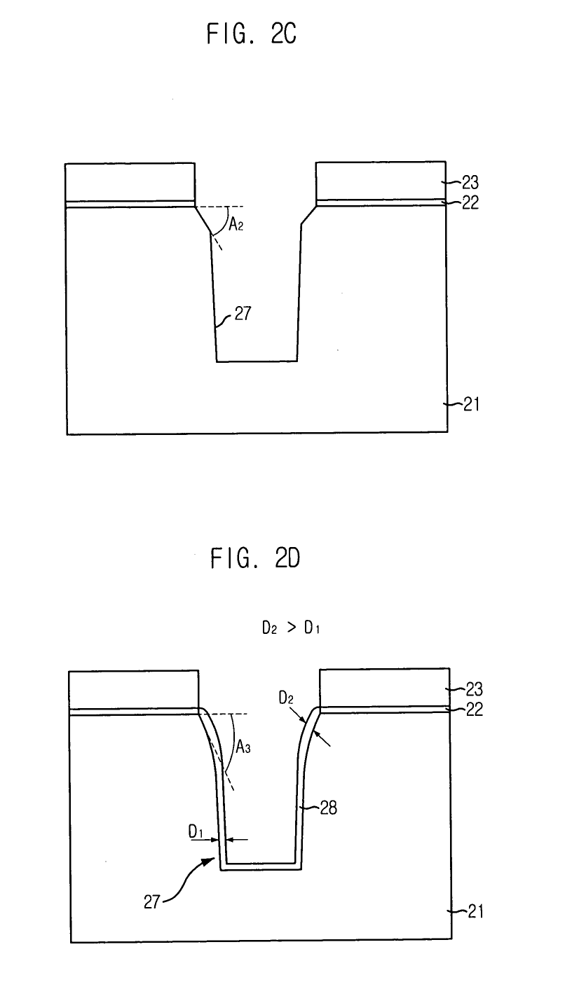

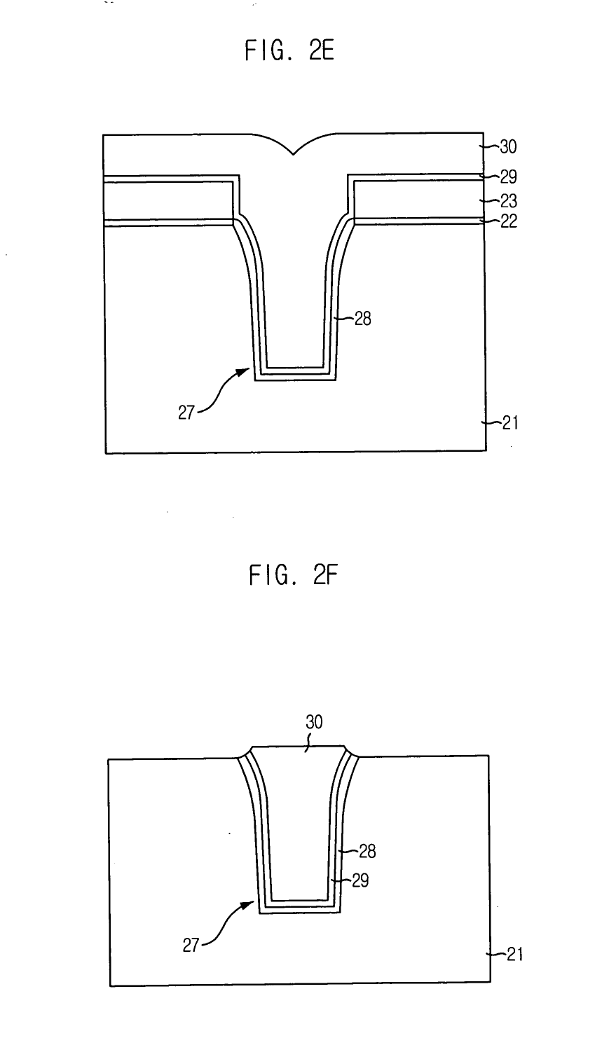

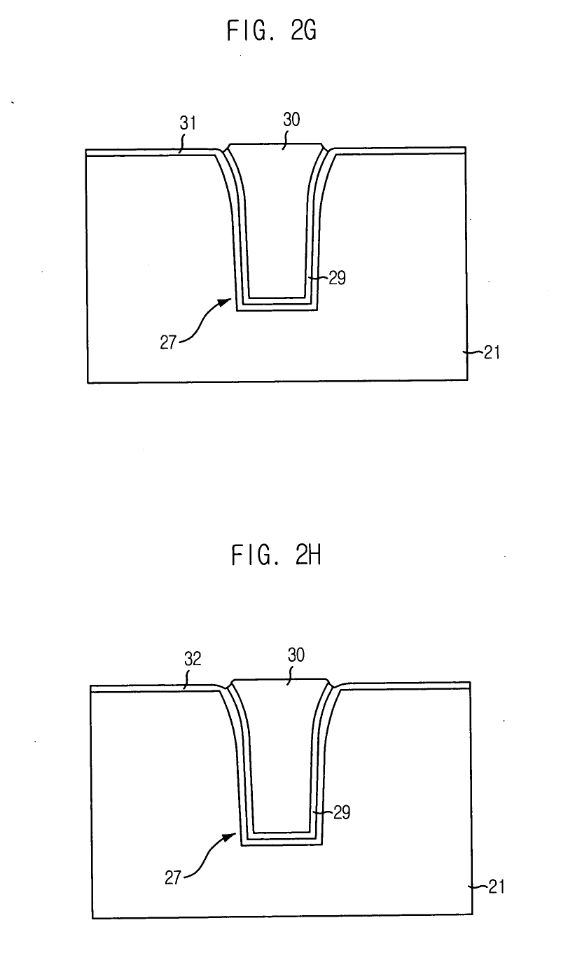

FIG. 3A is a detailed diagram showing angular changes of the top corner of the trench 27 during the steps of etching the trench 27, performing the LET and the deposition of the liner nitride layer 29. FIG. 3B is a detailed diagram showing angular changes of the top corner of the trench 27 during the deposition of the screen oxide layer 31 and the gate oxide layer 32. FIG. 3C shows changes in a thickness of the oxide layers formed at the top corners of the trench 27.

Referring to FIG. 3A, during the trench etching process B1, the LET process B2 and the liner nitride layer deposition process B3, the top corner of the trench 27 changes its angle from about 45° to about 75° and eventually to about 90°.

Referring to FIG. 3B, during the screen oxide layer 31 deposition process B4 and the gate oxide layer 32 deposition process B5, the angle of the top corner of the trench 27 is maintained to be almost about 90° but a rounding shape of the top corner is changed. That is, since the dry oxidation technique is used in the screen oxide layer deposition process B4 and the gate oxide layer deposition process B5, the edged top corner of the trench 27 is also etched, thereby being more rounded. As a result of the continuous applications of the dry oxidation technique, the thickness D of the oxide layers formed at the top corners of the trench 27 also gradually increases and thus, the moat generation is minimized. These effects are shown in FIG. 3C.

During the trench etching, etching recipes for realizing angles of about 45°, about 30° and about 90° are described in the following table.

TABLE 1

| | Pad Nitride Layer Etching Device | | | | Silicon Etching Device | | | |
|---|---|---|---|---|---|---|---|---|
| | BRAC | Nit | Nit OE | TR | HBr | B/T | M/E | S/E |
| 45° | 83 mtorr | 83 mtorr | 88 mtorr | 88 mtorr | 10 mtorr | 10 mtorr | 10 mtorr | 10 mtorr |
| | 300 W | 600 W | 600 W | 600 W | 1000 Ws | 600 Ws | 1300 Ws | 1200 Ws |
| | 20 CHF₃ | 15 CHF₃ | 50 CF₄ | 40 CHF₃ | 275 Wb | 90 Wb | 275 Wb | 1 Wb |
| | 80 CF₄ | 5 CF₄ | 300 Ar | 10 CF₄ | 40 HBr | 80 CF₄ | 20 Cl₂ | 60 CF₄ |
| | 200 Ar | 300 Ar | EOP 10″ | 300 Ar | 10 torr He | 10 torr He | 60 HBr | 10 O₂ |
| | 12 O₂ | 2 O₂ | | EOP 20″ | 20° C. | 20° C. | 3 O₂ | 100 Ar |
| | EOP 25″ | EOP 16″ | | | EOP 0″ | EOP 7″ | 10 torr He | 10 torr He |
| | | | | | | | 20° C. | 20° C. |
| | | | | | | | EOP 24″ | EOP 15″ |
| 30° | 83 mtorr | 88 mtorr | 88 mtorr | 88 mtorr | 10 mtorr | 10 mtorr | 10 mtorr | 10 mtorr |
| | 300 W | 600 W | 600 W | 600 W | 1000 Ws | 600 Ws | 1300 Ws | 1200 Ws |
| | 20 CHF₃ | 15 CHF₃ | 50 CF₄ | 40 CHF₃ | 275 Wb | 90 Wb | 275 Wb | 1 Wb |
| | 80 CF₄ | 5 CF₄ | 300 Ar | 10 CF₄ | 40 HBr | 80 CF₄ | 20 Cl₂ | 60 CF₄ |
| | 200 Ar | 300 Ar | EOP 0″ | 300 Ar | 10 torr He | 10 torr He | 60 HBr | 10 O₂ |
| | 12 O₂ | 2 O₂ | | EOP 20″ | 20° C. | 20° C. | 3 O₂ | 100 Ar |
| | EOP 25″ | EOP 16″ | | | EOP 5″ | EOP 0″ | 10 torr He | 10 torr He |
| | | | | | | | 20° C. | 20° C. |
| | | | | | | | EOP 24″ | EOP 15″ |
| 90° | 83 mtorr | 83 mtorr | 88 mtorr | 88 mtorr | 10 mtorr | 10 mtorr | 10 mtorr | 10 mtorr |
| | 300 W | 600 W | 600 W | 600 W | 1000 Ws | 600 Ws | 1300 Ws | 1200 Ws |
| | 20 CHF₃ | 15 CHF₃ | 50 CF₄ | 40 CHF₃ | 275 Wb | 90 Wb | 275 Wb | 1 Wb |
| | 80 CF₄ | 5 CF₄ | 300 Ar | 10 CF₄ | 40 HBr | 80 CF₄ | 20 Cl₂ | 60 CF₄ |
| | 200 Ar | 300 Ar | EOP 0″ | 300 Ar | 10 torr He | 10 torr He | 60 HBr | 10 O₂ |
| | 12 O₂ | 2 O₂ | | EOP 20″ | 20° C. | 20° C. | 3 O₂ | 100 Ar |
| | EOP 25″ | EOP 16″ | | | EOP 0″ | EOP 7″ | 10 torr He | 10 torr He |
| | | | | | | | 20° C. | 20° C. |
| | | | | | | | EOP 24″ | EOP 15″ |

In Table 1, BARC, Nit, Nit OE, TR and HBr express a recipe for etching the anti-reflection layer 24, that for etching the pad nitride layer 23, that for over-etching the pad nitride layer 23, that for etching the top rounded surface 26 and that for etching the original silicon substrate 21, respectively. Also, the B/T abbreviated from ‘break through’ expresses a recipe for etching the native oxide layer. The M/E abbreviated from ‘main etch’ expresses a recipe for etching the trench 27. The S/E abbreviated from ‘soft etch’ expresses the LET of the trench 27. Also, the units Ws and Wb express the source power and the bias power, respectively.

Based on Table 1, among the above described various etch recipes, the etch recipe that differentiates an angle of the top corners of the trench is employed in the steps of over-etching the pad nitride layer 23, etching the silicon substrate 21 with use of HBr and removing the native oxide layer. Preferably, the angle of the top corners of the trench 27 varies by an etching time.

Referring to Table 1, the step of over-etching the pad nitride layer 23 proceeds under a common recipe of a pressure of about 88 mtorr, a power of about 600 W, CF₄ with about 50 sccm and Ar with about 300 sccm but at different etching times of about 0″, about 10″ and about 0″ so that the top corners of the trench have an angle of about 30°, about 45° and about 90°, respectively.

Also, the step of etching the silicon substrate 21 with use of HBr proceeds under a common recipe of a pressure of about 10 mtorr, a source power of about 1000 W, a bias power of about 275 W, HBr with about 40 sccm, He with about 10 torr and a temperature of about 20° C. but at different etching times of about 5″, about 0″ and about 0″ so that the top corners of the trench have an angle of about 30°, about 45° and about 90°, respectively.

Furthermore, the step of removing the native oxide layer proceeds under a common recipe of a pressure of about 10 mtorr, a source power of about 600 W, a bias power of about 90 W, CF₄ with about 80 sccm, He with about 10 torr and a temperature of about 20° C. but at different etching times of about 0″, about 7″ and about 7″ so that the top corners of the trench have an angle of about 30°, about 45° and about 90°, respectively.

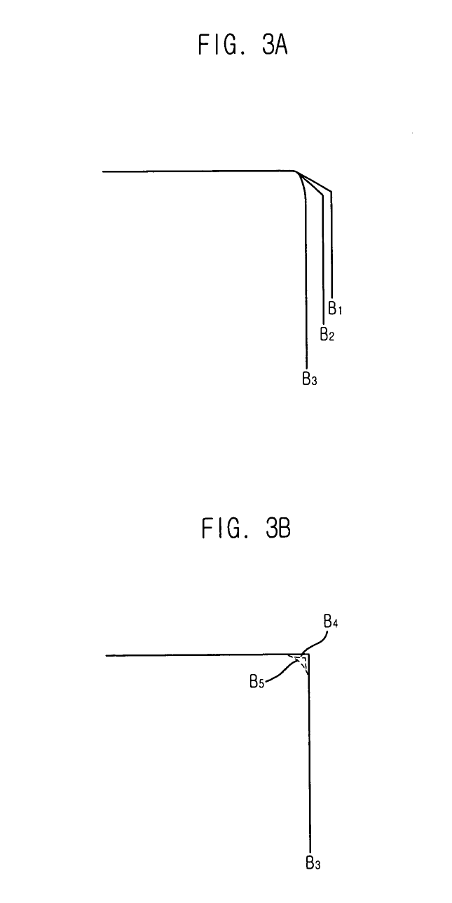

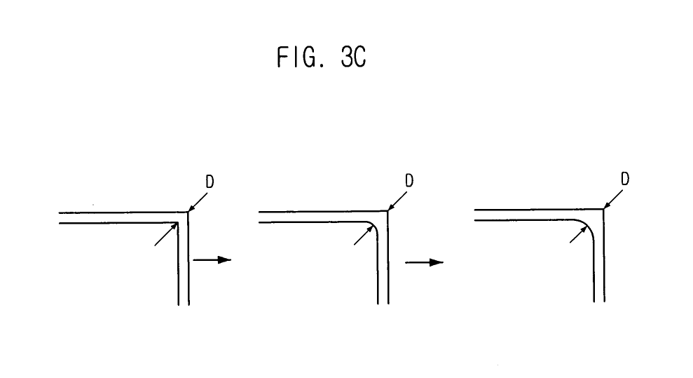

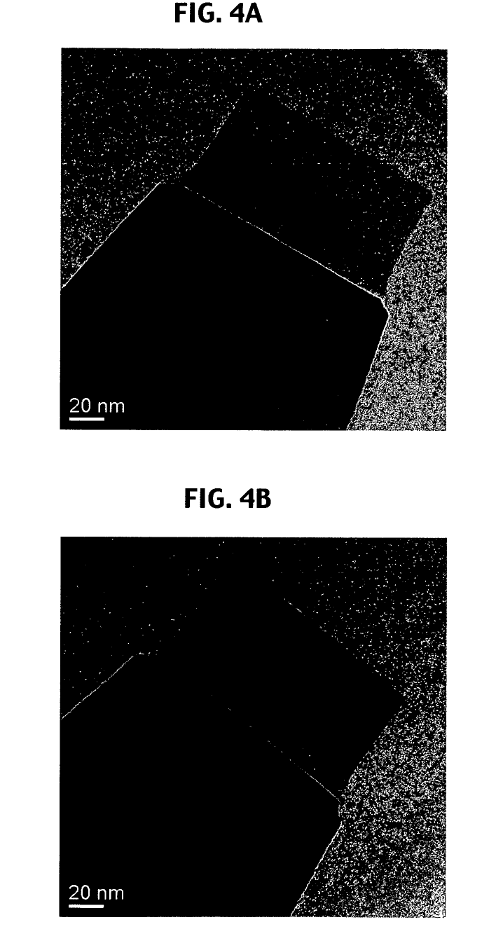

FIG. 4A is a micrograph showing the top corners of the trench having an angle of about 30° formed based on the etch recipe described in Table 1. FIG. 4B is a micrograph showing the top corners of the trench having an angle of about 45° formed based on the etch recipe described in Table 1. FIG. 4C is a micrograph showing the top corners of the trench having an angle of about 90° formed based on the etch recipe described in Table 1.

In addition to the etching time, an angle of the top corners of the trench can be controlled by varying a flow quantity of an etch gas and a pressure.

According to the preferred embodiment of the present invention, the etch recipe for making the top corners of the trench have an angle ranging from about 30° to about 60° is set, and the LET is then performed to control the top corners to have an angle of about 50° to about 80°.

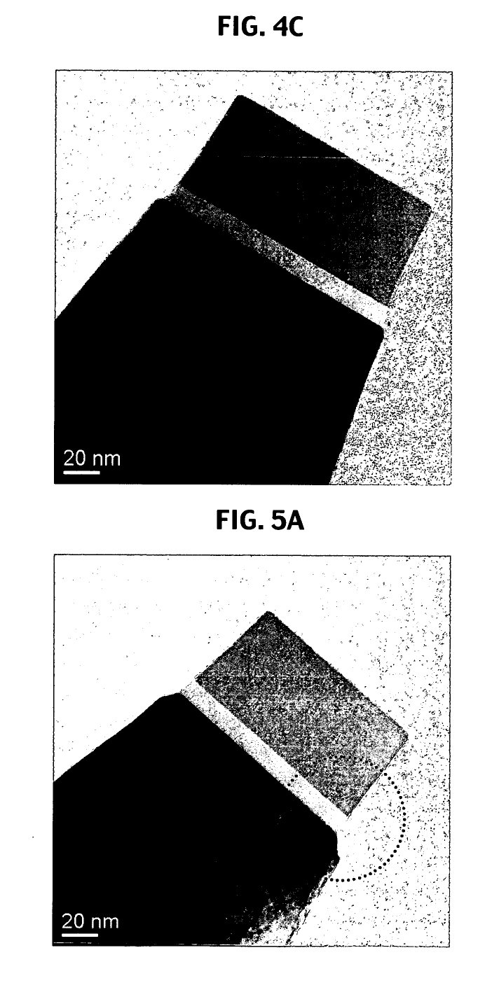

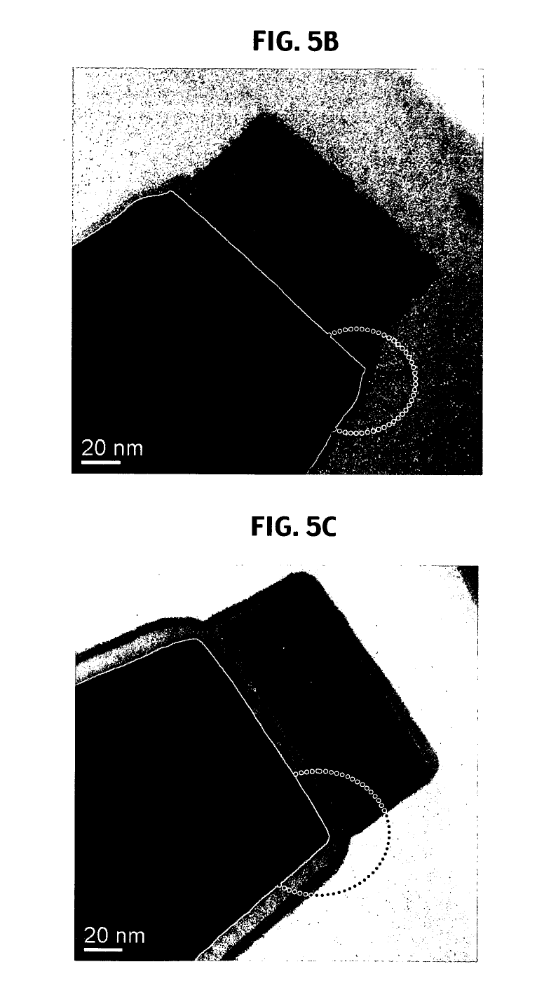

FIGS. 5A to 5C are micrographs showing the resultant structure obtained by performing the LET subsequent to the step of controlling the top corners of the trench to have an angle of about 45° and depositing the liner nitride layer. FIG. 5 is a micrograph showing the resultant structure obtained by depositing the liner nitride layer without performing the LET.

Based on the above described etch recipes, the top corners of the trench have an angle of about 45° (refer to FIG. 5A), and then, the LET is performed for about 14″ to make the angle of the top corners be about 75° (refer to FIG. 5B). Thereafter, the liner nitride layer is deposited (refer to FIG. 5C). Therefore, the top corners of the trench become rounded by performing the LET.

As shown in FIG. 5D, in case of performing the liner nitride layer without performing the LET, the top corners of the trench are very steep since a profile of the etched trench is almost maintained.

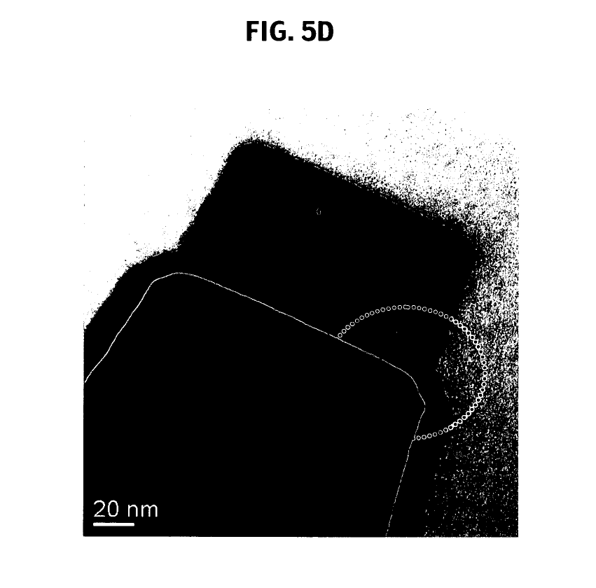

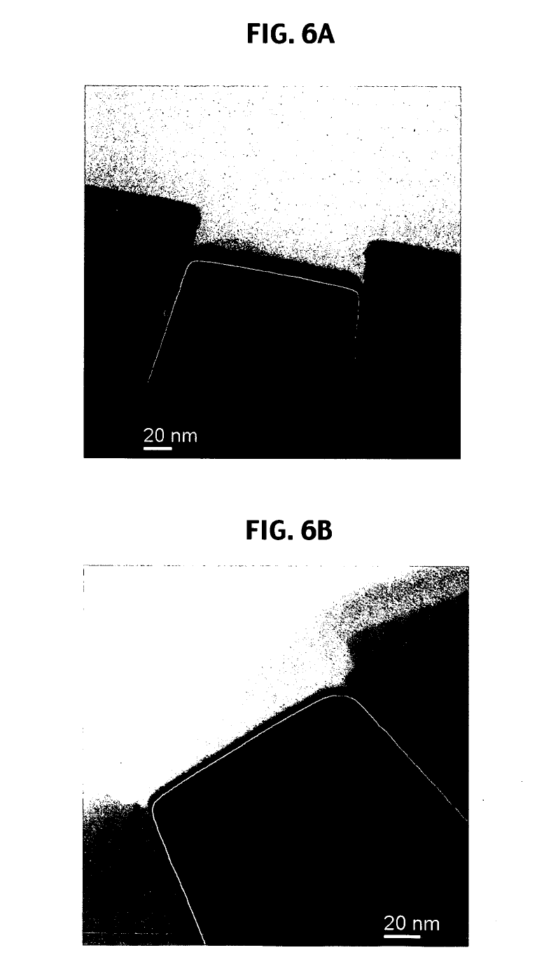

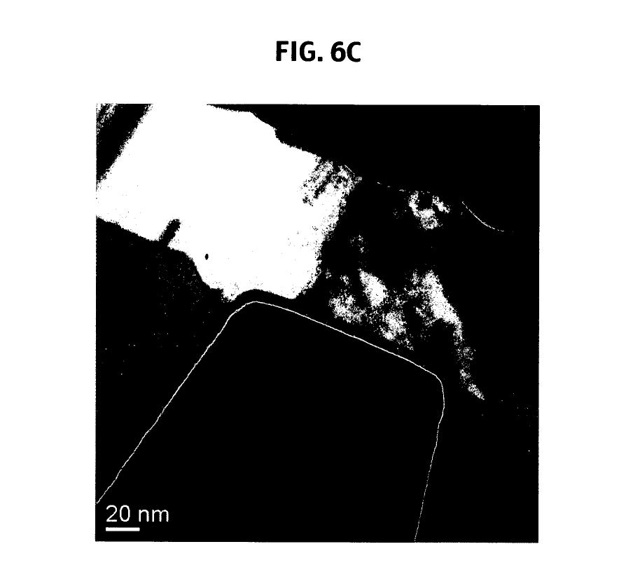

FIG. 6A is a micrograph showing the resultant structure of removing the pad nitride layer after the deposition of the liner nitride layer as shown in FIG. 5C. FIG. 6B is a micrograph showing the resultant structure after the formation of the screen oxide layer. FIG. 6C is a micrograph showing the resultant structure after the formation of the gate oxide layer.

As shown in FIGS. 6A to 6C, a moat profile is improved after the screen oxide layer and the gate oxide layer formation. The improvement is achieved by maintaining the angle of the top corners of the trench to be nearly about 90° through the use of the dry oxidation technique.

Meanwhile, the width of an active region can be also decreased by performing the LET. However, with the consideration that the LET is mainly for providing an effect of rounding the top corners of the trench, the effect on decreasing the width of the active region by the LET is not pronounced.

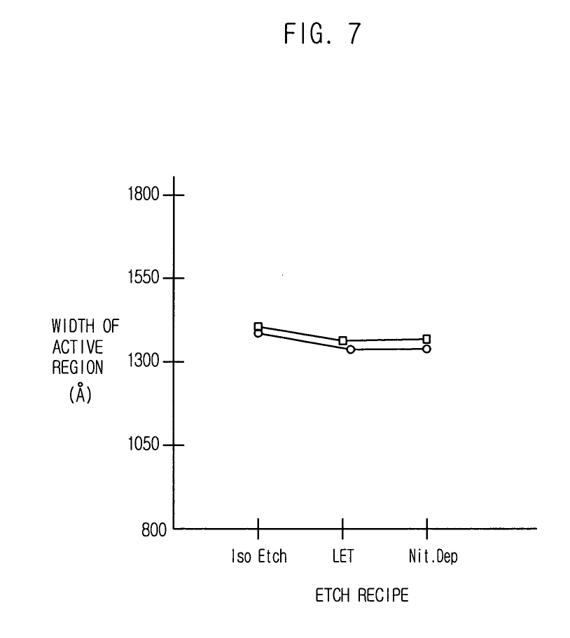

FIG. 7 is a graph comparing the decrease in the width of the active region with performing the LET to that in the width of the active region without performing the LET. In FIG. 7, the horizontal coordinate expresses etch recipes while the vertical coordinate expresses the width of the active region. Also, the reference symbols ‘0’ and ‘_’ represent a case of performing the LET and that of not performing the LET, respectively.

As shown, a difference between the widths of the active region with and without performing the LET is small.

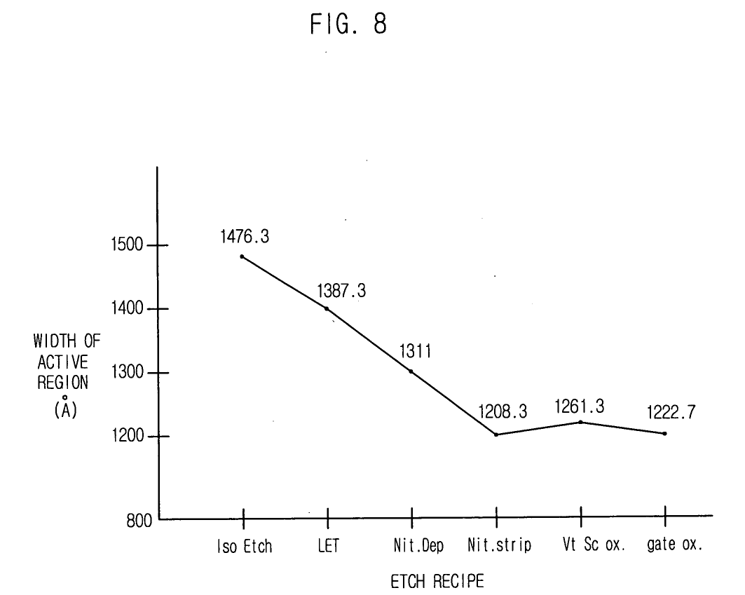

FIG. 8 is a graph showing changes in the width of the active region after the pad nitride layer is striped away. In FIG. 8, the horizontal coordinate expresses etch recipes while the vertical coordinate expresses the width of the active region.

Referring to FIG. 8, during the steps of performing the etching to the trench ISO Etch, the LET, the deposition of the liner nitride layer Nit. Dep and the strip process Nit. Strip to the pad nitride layer, the width of the active region gradually decreases to an descending order of about 1476.3 Å, about 1387.3 Å, about 1311 Å and about 1208 Å. However, this gradual decrease in the width of the active region is not recognizable in the steps of forming the screen oxide layer Vt Sc ox. and forming the gate oxide layer gate ox. That is, after the pad nitride layer is stripped away, only the angle of the top corners of the trench changes.

The preferred embodiment of the present invention provides an effect of minimizing the moat generation by controlling the top corners of the trench to be rounded and thereby preventing degradation of the device isolation layer. Also, according to the present invention, the LET is performed after the trench is etched so that damaged layers from this etching are removed. These series of the etching steps results in an increase in yields of semiconductor devices.

While the present invention has been described with respect to certain preferred embodiments, it will be apparent to those skilled in the art that various changes and modifications may be made without departing from the scope of the invention as defined in the following claims.

What is claimed is:

1. A method for forming a device isolation layer of a semiconductor device, comprising the steps of:
forming a pad layer pattern defining a device isolation layer on a substrate;
forming a trench by etching an exposed portion of the substrate with use of the pad layer pattern as a mask;
performing an etching process to make top corners of the trench rounded;
forming a lateral oxide layer by oxidating sidewalls of the trench formed after the etching process;
forming a liner nitride layer on the lateral oxide layer;
forming an insulation layer on the liner nitride layer to fill the trench; and
planarizing the insulation layer.

2. The method as recited in claim 1, wherein the step of forming the trench proceeds by controlling an angle of the top corners of the trench to be in a range from about 30° to about 600 through the use of a gas containing at least hydrogen bromide and chlorine gas.

3. The method as recited in claim 2, wherein the step of forming the trench includes the steps of:
performing an etching process by using hydrogen bromide;
removing a native oxide layer formed after the etching process by using carbon tetrafluoride (CF₄) gas;
performing an etching process with use of a gas containing hydrogen bromide and chloride gas to form the trench with a predetermined depth; and
performing an etching process by using a gas containing CF₄ and oxygen (O₂) gas to purge the chloride gas from a chamber.

4. The method as recited in claim 1, wherein the etching process proceeds by employing an isotropic etching technique.

5. The method as recited in claim 4, wherein an angle of top corners of the trench ranges from about 500 to about 80° through the use of the isotropic etching technique.

6. The method as recited in claim 4, wherein the isotropic etching technique uses a gas containing CF₄ and O₂ gas.

7. The method as recited in claim 1, wherein the step of forming the lateral oxide layer proceeds by employing a dry oxidation technique.

8. The method as recited in claim 7, wherein the dry oxidation technique is performed at a temperature of about 900° C. to about 1000° C. to form the lateral oxide layer with a thickness ranging from about 60 Å to about 100 Å.

9. A method for fabricating a semiconductor device, comprising the steps of:
forming a trench of which top corners are rounded by etching a surface of a substrate to a predetermined depth;
performing an etching process to the trench so that the top corners of the trench become more rounded;
forming a lateral oxide layer by oxidating sidewalls of the trench;
forming a liner nitride layer on the lateral oxide layer;
forming an insulation layer on the liner nitride layer to bury the trench;
planarizing the insulation layer until a surface of the substrate is exposed;
forming an oxide layer on the exposed surface of the substrate; and
forming a conductive layer for a gate electrode on an entire surface of a structure containing the oxide layer.

10. The method as recited in claim 9, wherein the step of forming the oxide layer includes the steps of:
forming a screen oxide layer for a threshold voltage control on the substrate;
implanting a dopant for a threshold voltage control by using the screen oxide layer as a mask;
removing the screen oxide layer; and
forming a gate oxide layer on an exposed surface of the substrate after removing the screen oxide layer.

11. The method as recited in claim 9, wherein the lateral oxide layer is formed through a dry oxidation technique.

12. The method as recited in claim 10, wherein the screen oxide layer and the gate oxide layer are formed through a dry oxidation technique.

13. The method as recited in claim 11, wherein the lateral oxide layer is formed at a temperature ranging from about 900° C. to about 1000° C. with a thickness in a range from about 60 Å to about 100 Å.

14. The method as recited in claim 12, wherein the screen oxide layer is formed at a temperature ranging from about 850° C. to about 1000° C. with a thickness in a range from about 50 Å to about 150 Å.

15. The method as recited in claim 12, wherein the gate oxide layer is formed at a temperature ranging from about 850° C. to about 1000° C.

16. The method as recited in claim 9, wherein at the step of forming the trench of which top corners are rounded, the top corners of the trench are rounded in an angle of about 30° to about 60° with use of a gas containing at least hydrogen bromide and chlorine gas.

17. The method as recited in claim 16, wherein the step of forming the trench further includes the steps of:
performing an etching process by using hydrogen bromide;
removing a native oxide layer formed after the etching process by using CF₄ gas;
performing an etching process by using a gas containing hydrogen bromide and chlorine gas until the trench has a predetermined depth; and
performing an etching process with use of a gas containing CF₄ and O₂ gas to purge chlorine gas from a chamber.

18. The method as recited in claim 9, wherein the step of making the top corners of the trench more rounded proceeds by employing an isotropic etching technique.

19. The method as recited in claim 18, wherein the top corners of the trench is controlled to have an angle ranging from about 50° to about 80° through the use of the isotropic etching technique.

20. The method as recited in claim 18, wherein the isotropic etching technique proceeds by using a gas containing CF₄ and O₂ gas.
